(19) United States
(12) Patent Application Publication
(10) Pub. No.: US 2012/0195024 A1
(43) Pub. Date: Aug. 2, 2012

(54) FLEXIBLE CIRCUIT BOARD CONNECTION STRUCTURE AND DISPLAY DEVICE

(75) Inventors: Hiroshi Kawaguchi, Osaka (JP); Isao Kajima, Osaka (JP)

(73) Assignee: SHARP KABUSHIKI KAISHA, Osaka (JP)

(21) Appl. No.: 13/501,146

(22) PCT Filed: Sep. 9, 2010
(86) PCT No.: PCT/JP2010/065488

§ 371 Date: Apr. 10, 2012

(30) Foreign Application Priority Data
Oct. 14, 2009 (JP) 2009-237486

(51) Int. Cl. G09F 13/04; H05K 1/14

(52) U.S. Cl. 362/97.2; 362/97.1; 361/803

(57) ABSTRACT

Disclosed is a flexible circuit board connection structure that has a simple configuration, is inexpensive, and has superior connection reliability. The connection structure is a structure connecting a first flexible circuit board 40 and a second flexible circuit board 50 and is characterized in that a first through-hole 45 and a second through-hole 46 are formed in the first flexible circuit board 40, the second flexible circuit board 50 is inserted through the first through-hole 45 from the first surface 48 side of the first flexible circuit board 40 to the second surface 49 side of the same, and the second flexible circuit board 50, which has been inserted through to the second surface 49 side of the first flexible circuit board 40, is soldered to the first flexible circuit board 40 from the first surface 48 side of the first flexible circuit board 40 via the second through-hole 46.

### TECHNICAL FIELD

The present invention relates to a display device and a connection structure of a flexible circuit board.

### BACKGROUND ART

Display devices, as represented by portable terminal equipment such as cellular phones, PDAs, or the like, and televisions, personal computer displays, or the like, are equipped internally with numerous electronic components. These electronic components are connected to one another electrically by a circuit board or the like. In recent years, as display devices have been miniaturized and made more light-weight, attempts have been made to reduce as much as possible the space occupied by the circuit board. In order to attain such space reduction, there has been an adoption of flexible circuit boards that are capable of being freely bent and folded (Patent Document 1).

The aforementioned Patent Document 1 discloses a structure for connection between flexible circuit boards.

Specifically, this is a substrate connection structure for inserting a flexible substrate into an insertion hole provided in a fixed substrate having a wiring pattern, and then for soldering and fixing. The aforementioned flexible substrate is provided with a slant part formed of dimensions that become progressively larger than an aperture width of an insertion hole of the aforementioned fixed substrate in order from front to back along the insertion direction, an attachment part formed of dimensions smaller than the aforementioned aperture width of the insertion hole and positioned to the rear of the tilted part, and a stopper part formed of dimensions larger than the aforementioned aperture width of the insertion hole and positioned to the rear of the attachment part. In the flexible substrate connection structure, the aforementioned attachment part engages with the insertion hole of the aforementioned fixed substrate, and the wiring patterns of both aforementioned substrates are soldered and fixed together.

### RELATED ART DOCUMENT

### Patent Documents

Patent Document 1: Japanese Utility Model Application Laid-Open Publication No. H4-87675.

### PROBLEMS TO BE SOLVED BY THE INVENTION

When flexible circuit boards are connected together by soldering, normally the soldering iron is held in one hand, and the other hand holds the solder wire. Thus, there frequently are difficulties during positioning of the soldering location by hand. Thus, often the terminal to be soldered is positioned, and then a double-sided tape, fixing tape, or a jig is used to fix the position of the soldering location. However, the double-sided tape or fixing tape used for positioning by this procedure results in increased cost, and thus this procedure is preferably not used.

The non-tape type fixing procedure of the aforementioned Patent Document 1 fixes the flexible circuit board to the insertion hole of the fixed substrate. However, when stress is applied to the inserted flexible circuit board, connection stress concentrates at the soldered part, and there are instances where cracks are generated in the solder and the connection fails. In order to prevent the occurrence of such failure, a means becomes necessary such as attachment of double-sided tape or gluing together or the like so that the concentrated stress can be endured, and this results in increased cost.

### SUMMARY OF THE INVENTION

Based on the aforementioned circumstances, an object of the present invention is to provide a flexible circuit board connection structure that has a simple structure, is inexpensive, and has excellent connection reliability. A further object of the present invention is to provide a display device that is equipped with such a connection structure.

### MEANS FOR SOLVING THE PROBLEMS

In order to solve the aforementioned problems, the flexible circuit board connection structure of the present invention is a connection structure between a first flexible circuit board and a second flexible circuit board where a first through-hole and a second through-hole are formed in the aforementioned first flexible circuit board, the aforementioned second flexible circuit board is inserted into the aforementioned first through-hole from a first surface side of the aforementioned first flexible circuit board to a second surface side, and the aforementioned second flexible circuit board inserted to the aforementioned second surface side of the aforementioned first flexible circuit board is soldered and connected to the aforementioned first flexible circuit board from the aforementioned first surface side of the aforementioned first flexible circuit board through the aforementioned second through-hole.

According to this type of connection structure, two through-holes are provided, the second flexible circuit board is inserted into the first through-hole, and this inserted second flexible circuit board is connected to the first flexible circuit board through the second through-hole. Thus, although stress can concentrate at the first through-hole (i.e., part into which the substrate is inserted) when stress is applied to the second flexible circuit board, there is no generation of cracks or the like at the solder part due to concentration of stress at the second through-hole (i.e., a soldered part), and connection failures become unlikely. Thus, there is no need for adoption of measures such as attachment of fixing tape or the like, and due to the connection structure being a simple structure providing two through-holes in the substrate, there is no accompanying cost increase.

In the aforementioned connection structure, the aforementioned first flexible circuit board may have, on at least the aforementioned first surface side, a first-side terminal, the aforementioned second flexible circuit board may have, on at least its first surface side, a second-side terminal, and the aforementioned second-side terminal may be disposed opposing the aforementioned second surface side of the aforementioned first flexible circuit board, while the aforementioned second-side terminal may be soldered and connected to the aforementioned first-side terminal of the aforementioned first flexible circuit board through the aforementioned second through-hole.

Due to soldering and connecting of the second-side terminal and the first-side terminal together in this manner through the second through-hole, reliability of the connection becomes extremely high.

Moreover, in a state where the aforementioned second flexible circuit board is inserted into the aforementioned first through-hole, the aforementioned first-side terminal of the aforementioned first flexible circuit board may be superimposed on the aforementioned second-side terminal of the aforementioned second flexible circuit board.

If a configuration is adopted such that the first-side terminal is superimposed on the second side-terminal in the state where the second flexible circuit board is inserted into the first through-hole, positioning is accomplished by inserting the second flexible circuit board into the first through-hole, and thus the work of positioning becomes greatly simplified.

Moreover, the aforementioned first through-holes may be disposed on the aforementioned first flexible circuit board in a zigzag pattern, and the aforementioned second-side terminals may be disposed on the aforementioned second flexible circuit board in a zigzag pattern.

For terminals disposed in a zigzag pattern in this manner, it becomes possible to easily perform the positioning required for connection.

Moreover, the hole width of the aforementioned first through-hole may be approximately the same as a substrate width of the aforementioned second flexible circuit board.

Due to approximate matching of the hole width and the substrate width in this manner, it becomes possible to achieve positioning for connection by passing the second flexible circuit board into the first through-hole.

Moreover, a protuberance may be provided in the aforementioned second flexible circuit board; the aforementioned protuberance may restrict insertion of the aforementioned second flexible circuit board into the aforementioned first through-hole to a certain amount.

Due to providing of the protuberance in this manner, the amount of insertion is restricted, and positioning in the direction of insertion becomes simplified.

Moreover, a protuberance projecting in the width direction of the aforementioned second flexible circuit board may be formed in the aforementioned second flexible circuit board, and the width of the substrate of the aforementioned second flexible circuit board including the aforementioned protuberance may be larger than hole width of the aforementioned first through-hole.

Due to providing of the protuberance in this manner, the amount of insertion is restricted, and positioning in the direction of insertion becomes simplified.

Moreover, a solder attachment land may be formed on the protuberance where the solder attachment land may be formed within the aforementioned first through-hole of the aforementioned first flexible circuit board and may be positioned overlapping the aforementioned protuberance of the second flexible circuit board inserted into the aforementioned first through-hole, and the aforementioned solder attachment lands may be fixed by soldering.

Due to addition of the soldering connection to the second through-hole in this case, and due to reinforcing connection and fixing by this solder attachment land, even when an external stress is applied to one of the substrates so that stress would occur at the solder connection part, there is resistance to failure such as the generation of cracks or the like at the solder part.

The aforementioned solder connection may be performed so as to bridge at least one part of the aforementioned second insertion-hole.

When a solder connection is performed in the form of bridging at least one part of the second insertion-hole in this manner, connections are performed between the ends of the hole (i.e., at two locations), and it thus becomes possible to strengthen this solder connection itself.

Next, in order to solve the aforementioned problems, the display device of the present invention is a display device having a touch panel and including: a main control part for performing display control; a touch panel control part for performing control of the touch panel; a first flexible circuit board connected to the aforementioned main control part; and a second flexible circuit board connected to the aforementioned touch panel control part; where the aforementioned first flexible circuit board and the aforementioned second flexible circuit board are connected together by the aforementioned connection structure.

If the aforementioned connection structure is achieved in a display device provided with a touch panel in this manner by connection together of flexible circuit boards relating to the touch panel control and display control, the display device is resistant to connection failure, and it becomes possible to inexpensively provide a highly reliable display device.

Next, in order to solve the aforementioned problems, the display device of the present invention is a display device having a backlight and including: a main control part for performing display control; a backlight control part for control of the backlight; a first flexible circuit board connected to the aforementioned main control part; and a second flexible circuit board connected to the aforementioned backlight control part; where the aforementioned first flexible circuit board and the aforementioned second flexible circuit board are connected together by the aforementioned connection structure.

If the aforementioned connection structure is achieved by a display device provided with a backlight in this manner by connection together of flexible circuit boards relating to the backlight control and display control, the display device is resistant to connection failure, and it becomes possible to inexpensively provide a highly reliable display device.

Furthermore, the aforementioned main control part may perform display control of a liquid crystal panel.

There is high demand for reduced weight for this type of liquid crystal display device, and by adopting the connection structure for flexible circuit boards in the manner of the present invention, it is possible to contribute to the further reduction of weight of liquid crystal display devices.

### EFFECTS OF THE INVENTION

According to the present invention, it becomes possible to provide a flexible circuit board connection structure that has excellent connection reliability and is inexpensive and has a simple structure. Moreover, the present invention makes it possible to provide a display device equipped with such a connection structure.

### BRIEF DESCRIPTION OF THE DRAWINGS

FIG. 1 is a block diagram showing the schematic structure of a liquid crystal display device that is an embodiment of the present invention.

FIG. 2 is a top view showing a flexible circuit board connection structure provided in the liquid crystal display device of FIG. 1.

FIG. 3 is a cross-sectional drawing showing a flexible circuit board connection structure provided in the liquid crystal display device of FIG. 1.

FIG. 4 is a drawing for explanation of the operation of the flexible circuit board connection structure provided for the liquid crystal display device of FIG. 1.

FIG. 5 is a top view showing a first modified example of the connection structure of the flexible circuit board.

FIG. 6 is a drawing for explanation of the operation of the connection structure of FIG. 5.

FIG. 7 is a top view showing a second modified example of the connection structure of the flexible circuit board.

FIG. 8 is a cross-sectional view along the line A-A in FIG. 7.

FIG. 9 is a drawing for explanation of the operation of the connection structure of FIG. 7.

FIG. 10 is a top view showing a third modified example of the connection structure of the flexible circuit board.

FIG. 11 is a cross-sectional drawing showing a comparative example of the connection structure of the flexible circuit board.

FIG. 12 is a cross-sectional drawing showing a comparative example of the connection structure of the flexible circuit board.

### DETAILED DESCRIPTION OF EMBODIMENTS

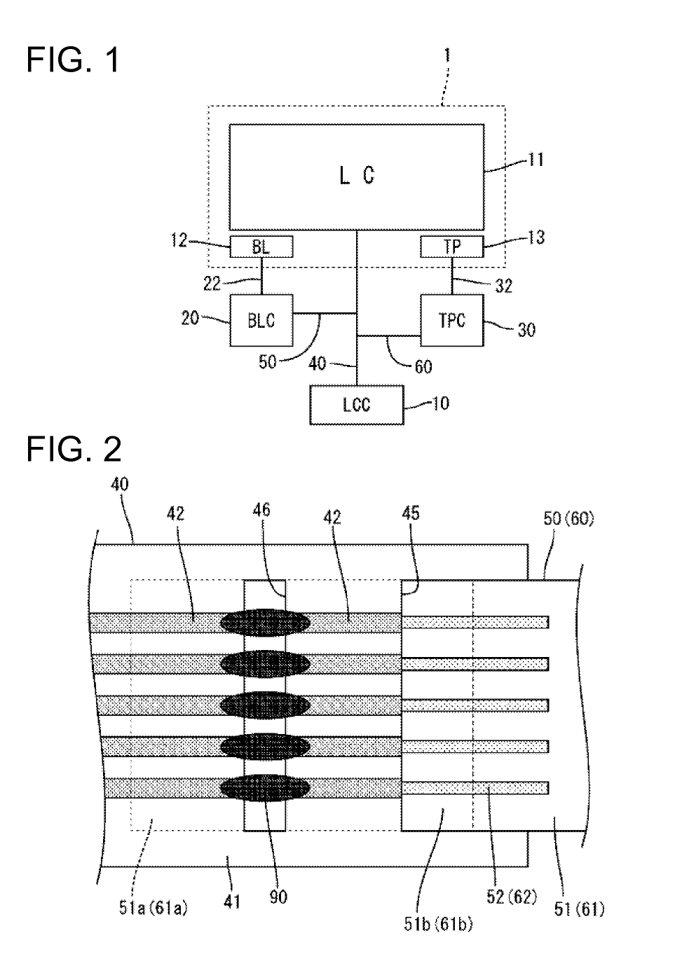

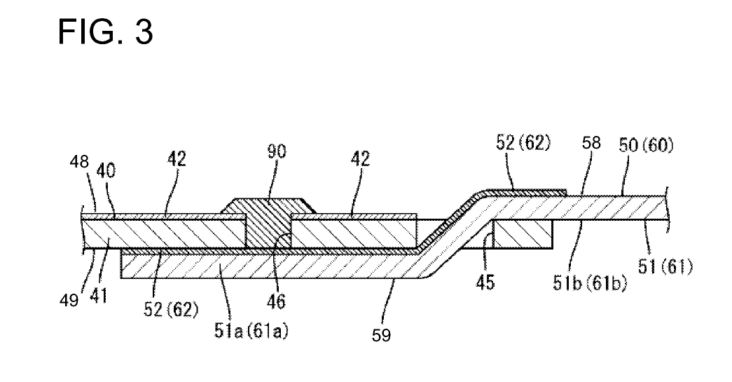

An embodiment of the present invention will be explained using FIGS. 1 to 4.

An example of a liquid crystal display device (display device) 1 of the present invention is shown, and this liquid crystal display device 1 is equipped with a liquid crystal panel 11, a backlight 12, and a touch panel 13. This liquid crystal display device 1 is suitable for use, for example, as a small-scale display device of a cellular phone or the like.

The liquid crystal panel 11 retains a liquid crystal layer sandwiched between a pair of substrates. Voltage applied to the liquid crystal layer by an external main control part 10 is controlled for each pixel, and display control is performed based on such control. This liquid crystal panel 11 and the main control part 10 are connected by the main flexible circuit board 40, and the main flexible circuit board 40 can be retained while being folded over. Thus, the liquid crystal display device 1 is advantageous, for example, in the construction of a small-scale display of a cellular phone monitor or the like.

The backlight 12 provides the liquid crystal panel 11 with illumination light for display. The supply of electrical power is controlled by an external backlight control part 20 in order to adjust lighting. This backlight 12 and the backlight control part 20 are connected together by the flexible circuit board 22, and the backlight control part 20 is connected to the main flexible circuit board 40 through the backlight flexible circuit board 50 so that signals can be exchanged with the main control part 10. These flexible circuit boards 22 and 50 can be contained within the display device by being folded over in the same manner as the main flexible circuit board 40.

The touch panel 13 is an input device and includes a transparent panel for sensing coordinates. Data input or the like is performed by the use of a touch pen, finger, or the like to touch the display face of this panel. The inputted data are transmitted to the touch panel control part 30, and based on these data, the display information displayed by the liquid crystal panel 11 is determined. This touch panel 13 and the touch panel control part 30 are connected together by the flexible circuit board 32, and the touch panel control part 30 is connected to the main flexible circuit board 40 through the touch panel flexible circuit board 60 so that signals can be exchanged with the main control part 10. These flexible circuit boards 32 and 60 can be contained within the display device by being folded over in the same manner as the main flexible circuit board 40.

The flexible circuit boards of the present embodiment in this manner are connected together, and this connection is achieved specifically by soldering connections. The connection structure between flexible circuit boards provided for the liquid crystal display device 1 will be explained below in detail.

Due to the progress of high density mounting of electronic display equipment such as those of cellular phones or the like, and due to demand for weight reduction, highly flexible circuit boards have been adopted that, due to flexibility, have a high degree of freedom of mounting. In the aforementioned manner, the present embodiment adopts flexible circuit boards 22 and 32, a main flexible circuit board 40, a backlight flexible circuit board 50, a touch panel flexible circuit board 60, or the like. Moreover, the flexible circuit boards of the present embodiment are connected together, and signals can be exchanged between the various control parts 10, 20, and 30. A connection structure for connection together of the flexible circuit boards in this manner is exemplified by the connection structure between the main flexible circuit board 40 (first flexible circuit board) and the backlight flexible circuit board 50 or the touch panel flexible circuit board 60 (second flexible circuit board, sometimes generally referred to hereinafter as the flexible circuit board 50 (60)) shown in FIGS. 2 through 4.

As illustrated, the main flexible circuit board 40 and the flexible circuit board 50 (60) are connected together by the solder part 90. Two through-holes 45 and 46 are formed in the main flexible circuit board 40. Among these through-holes, the flexible circuit board 50 (60) is inserted into the first through-hole 45, and the flexible circuit board 50 (60) is soldered and connected to the main flexible circuit board 40 at the second through-hole 46.

On the main flexible circuit board 40, a connection terminal (first-side terminal) 42 is formed for providing connection to the flexible circuit board 50 (60) at the front surface (first surface) 48 side of the substrate 41 of the main flexible circuit board 40. On the other hand, on the flexible circuit board 50 (60), a connection terminal (second-side terminal) 52 (62) is formed on the front surface (first surface) 58 (68) side of the substrate 51 (61) of the flexible circuit board 50 (60) for providing a connection to the main flexible circuit board 40. Then the flexible circuit board 50 (60) is inserted from the front surface 48 side of the main flexible circuit board 40 toward the rear surface (second surface) 49 side. A reference numeral 59 (69) is assigned to the rear surface (second surface) side of the flexible circuit board 50 (60). Moreover, the connection terminal 42 is linearly shaped and has a structure that is separated by the second through-hole 46.

The inserted flexible circuit board 50 (60) has a distal-end side distal end part (inserted part) 51a (61a) separated by the first through-hole 45 from a proximal-end side proximal end part 51b (61b). Through the second through-hole 46, the connection terminal 52 (62) formed in the front surface 48 side of the distal end part 51a (61a) of the flexible circuit board 50 (60) is soldered and connected to the connection terminal 42 of the front surface 48 side of the main flexible circuit board 40. That is to say, the connection terminal 42 and the connection terminal 52 (62) are soldered and connected together from the front surface 48 side of the main flexible circuit board 40 through the second through-hole 46.

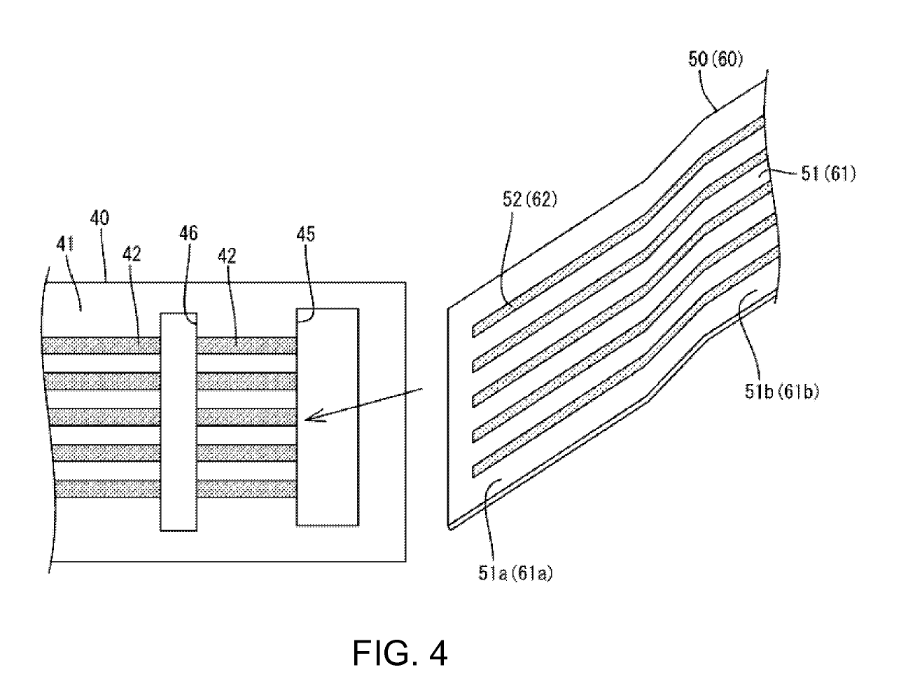

When such a soldering connection is to be performed, as shown in FIG. 4, the flexible circuit board 50 (60) is inserted into the first through-hole 45, and the distal end part 51a (61a) is led to the rear surface 49 side of the main flexible circuit board 40 so that the rear surface 49 faces the connection terminal 52 (62). Then, the flexible circuit board 50 (60) is inserted until the connection terminal 52 (62) opposes the second through-hole 46 of the main flexible circuit board 40, and both flexible circuit boards 40 and 50 (60) are positioned together.

Due to insertion of the flexible circuit board 50 (60) into the first through-hole 45 at this time, the flexible circuit board 50 (60) is positioned and fixed with respect to the first through-hole 45, and this eliminates mispositioning between both flexible circuit boards 40 and 50 (60). In particular, since the width of the substrate of the flexible circuit board 50 (60) is approximately the same as the hole width of the first through-hole 45 according to the present embodiment, it is quite difficult for mispositioning to occur.

Moreover, in the state in which the flexible circuit board 50 (60) is inserted into the first through-hole 45 in this manner (i.e., a state in which both flexible circuit boards 40 and 50 (60) are positioned together), the connection terminal 42 of the main flexible circuit board 40 and the connection terminal 52 (62) of the flexible circuit board 50 (60) overlap as viewed from above the substrates. Due to the connection terminal 42 of the main flexible circuit board 40 being separated linearly by the second through-hole 46, the connection terminal 52 (62) of the flexible circuit board 50 (60) exposed through the second through-hole 46 becomes positioned collinearly with the connection terminal 42 of the main flexible circuit board 40. Then the connection structure shown in FIGS. 1 to 3 is provided by soldering of each of the connection terminals 42 and 52 (62), collinearly arranged in this manner, through the second through-hole 46 from the front surface 48 side of the main flexible circuit board 40.

The solder connection is performed in the form of bridging at least one part of the second insertion-hole 46. That is to say, the connection terminal 42 of the main circuit board 40 that has been separated by the second through-hole 46 is extended in order to form a connection.

A liquid crystal display device 1 and a connection structure of the flexible circuit boards of the liquid crystal display device 1 of the present embodiment have been explained above. The operation and effect of the connection structure will be explained next.

According to the aforementioned connection structure, two through-holes are arranged in the main flexible circuit board 40, the flexible circuit board 50 (60) is inserted into the first through-hole 45, and the inserted flexible circuit board 50 (60) is connected to the main flexible circuit board 40 through the second through-hole 46. Thus, when stress is applied to the flexible circuit board 50 (60), although stress can concentrate at the first through-hole 45 (i.e., the part where the substrate is inserted), due to the difficulty of stress concentrating at the second through-hole 46 (i.e., the soldered part), there is no generation of cracking or the like at the solder part, and connection failure is inhibited. As a result, there is no need to adopt measures such as attaching fixing tape or the like, and the structure of the connection is simply formed by providing two through-holes in the main flexible circuit board 40. Thus, the connection is not accompanied by increased cost.

The main flexible circuit board 40 has at least the connection terminal 42 on the front surface 48 side, and the flexible circuit board 50 (60) has at least the connection terminal 52 on the front surface 58 side of the flexible circuit board 50 (60). The connection terminal 52 (62) is disposed facing the rear surface 49 of the main flexible circuit board 40, and the connection terminal 52 (62) is soldered and connected to the connection terminal 42 of the main flexible circuit board 40 through the second through-hole 46. In this manner, the flexible circuit board 50 (60) is inserted into the first through-hole 45, and the connection terminal 52 (62) and the connection terminal 42 are soldered and connected together through the second through-hole 46, and thus, these connections become highly reliable.

In the state in which the flexible circuit board 50 (60) is inserted into the first through-hole 45, the connection terminal 42 of the main flexible circuit board 40 overlaps the connection terminal 52 (62) of the flexible circuit board 50 (60). In the state in which the flexible circuit board 50 (60) is inserted into the first through-hole 45, due to the formation of a structure where the connection terminal 42 overlaps the connection terminal 52 (62) in this manner, positioning together of both substrates is accomplished by insertion of the flexible circuit board 50 (60) into the first through-hole 45, and the work required for such positioning together becomes very simple.

Moreover, the hole width of the first through-hole 45 is roughly the same as the substrate width of the flexible circuit board 50 (60). Thus, by insertion of the flexible circuit board 50 (60) into the first through-hole 45, it becomes possible to achieve positioning together for the connection.

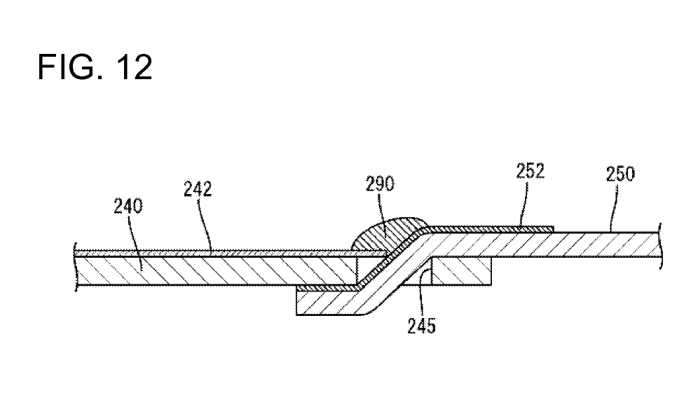

Moreover, a solder part 90 is formed over at least part of the second insertion-hole 46. Due to connections being performed at holes at both ends (i.e., at two locations), the solder connection itself becomes strengthened. That is to say, when soldering is performed by the solder part 190 by simply overlapping substrates 140 and 150 as shown in FIG. 11, the resultant connection occurs at one edge, and the necessity arises of fixing the connection by use of double-sided tape 161. Moreover, if a single through-hole 245 is provided in a first flexible circuit board 240 as shown in FIG. 12, if a second flexible circuit board 250 is inserted into the through-hole 245, and if a soldering connection is made by a solder part 290 at this insertion part, then this results in a connection at one end, and the reliability of the connection becomes low.

### Modified Examples

Several modified examples of the present embodiment will be explained next.

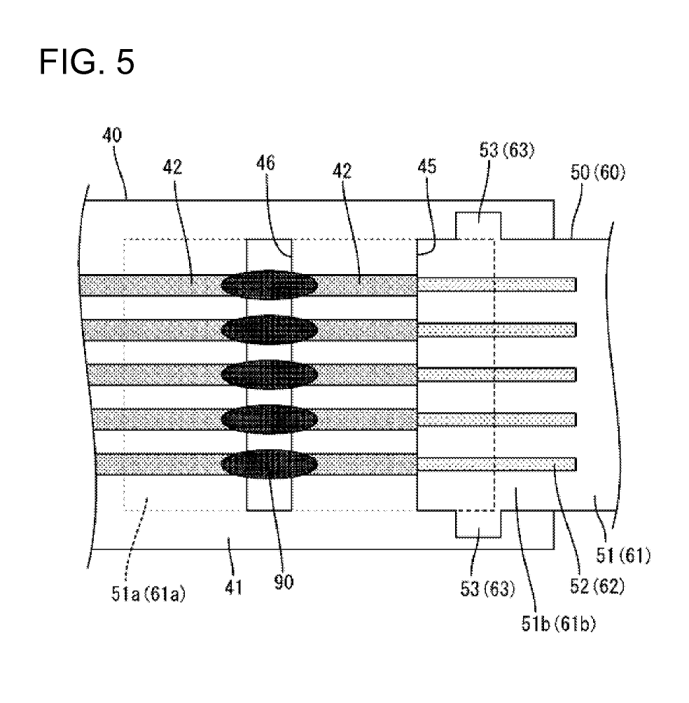

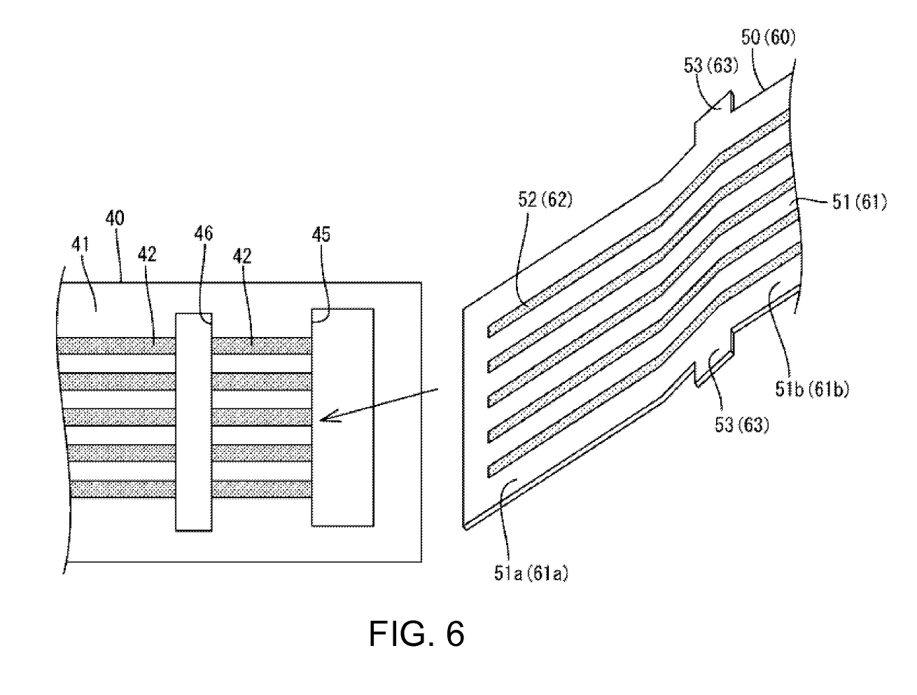

In the first modified example shown in FIGS. 5 and 6, a protuberance is provided in the flexible circuit board 50 (60). Specifically, at the width-direction edge parts of the substrate 51 (61), protuberances 53 (63) are formed that project in the width direction. The width of the flexible circuit board 50 (60), including these protuberances 53 (63), is made larger than the hole width of the first through-hole 45.

Due to providing of the protuberances 53 (63) in this manner, the amount of insertion of the flexible circuit board 50 (60) into the first through-hole 45 of the main flexible circuit board 40 is restricted, and this results in achievement of simple positioning together in the insertion direction.

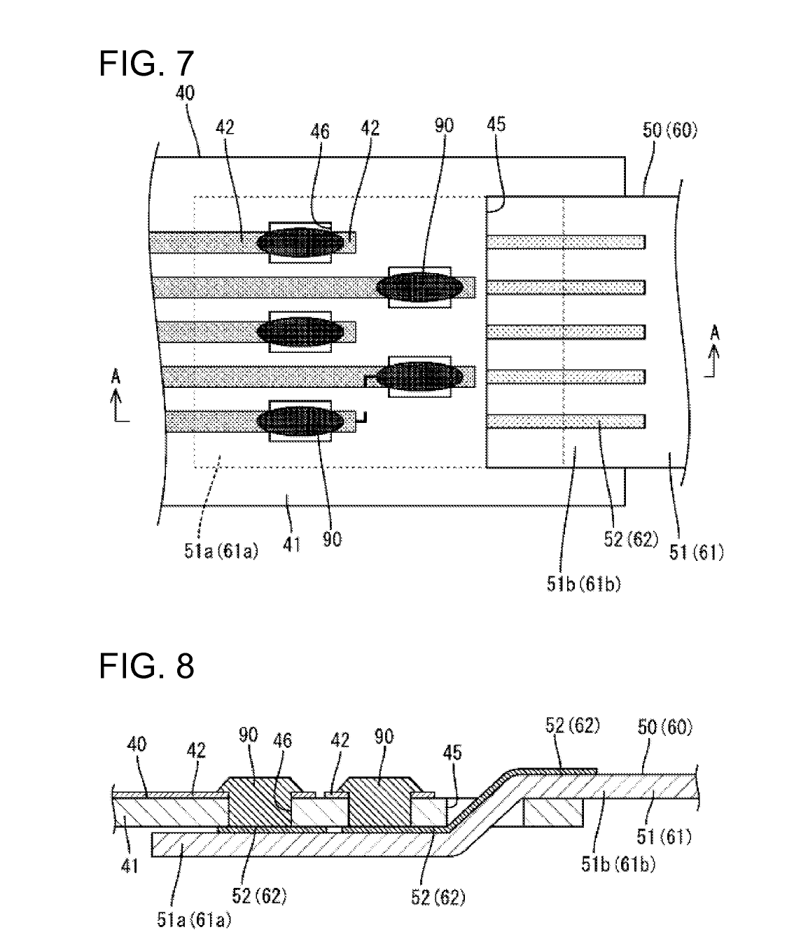

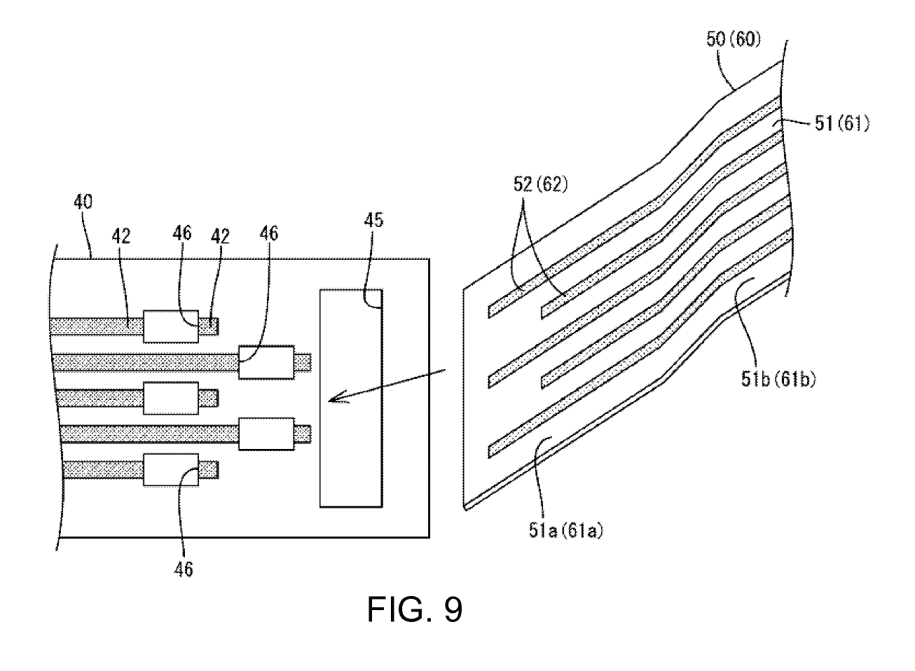

Next, in a second modified example shown in FIG. 7 through FIG. 9, the connection terminals 42 of the main flexible circuit board 40 are disposed in a zigzag pattern as viewed from above the substrate 41, and the first through-holes 46 are similarly disposed in a zigzag pattern as viewed from above. Connection terminals 52 (62) are also disposed on the flexible circuit board 50 (60) in a zigzag pattern as viewed from above.

When the connection terminals 42 and 52 (62) are disposed in a zigzag pattern in this manner, by adoption of a connection structure similar to that of the aforementioned embodiment, it is possible to easily perform positioning together for the connection. That is to say, although positioning together frequently becomes difficult when using a zigzag pattern of connection terminals, by adoption of the connection structure of the present embodiment, positioning together can be performed reliably even when the terminals are disposed in a zigzag pattern. Due to placement of the terminals in the zigzag pattern, even when the number of terminals is increased and the terminal pitch is narrowed, solder bridging seldom occurs, and current leakage is seldom generated.

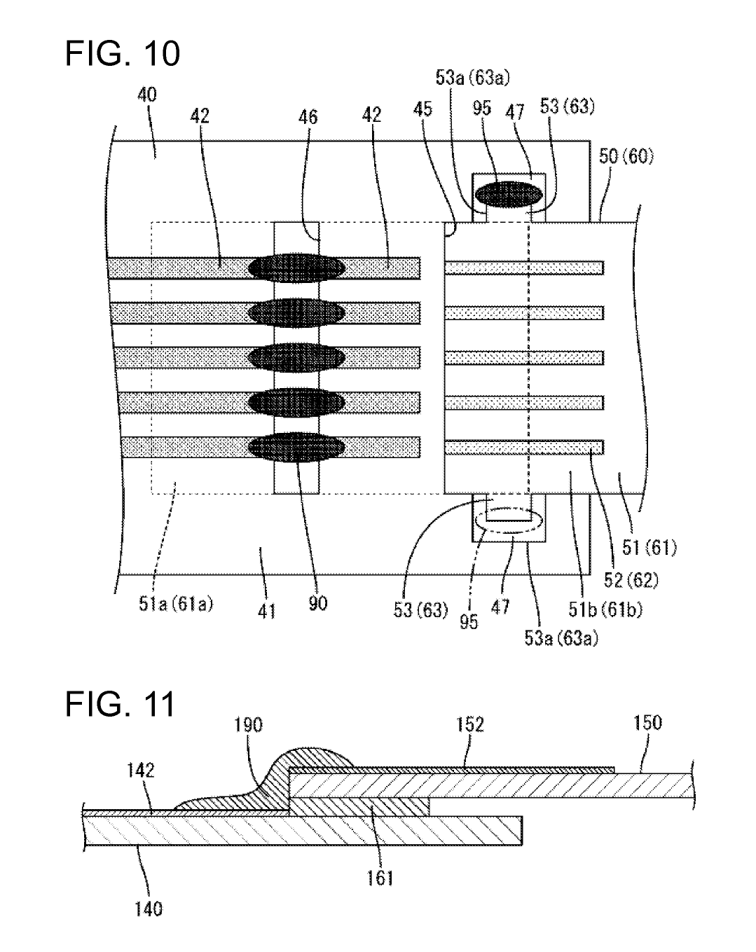

Next, in a third modified example shown in FIG. 10, protuberances 53 (63) are arranged on the flexible circuit board 50 (60) in a manner similar to the aforementioned first modified example. Solder attachment lands 53a (63a) are formed on these protuberances 53 (63), and solder attachment lands 47 are formed in the first through-hole 45 of the main flexible circuit board 40 at positions of overlap with the protuberances 53 (63) of the flexible circuit board 50 (60) inserted into the aforementioned first through-hole 45. The solder attachment lands 53a (63a) and 47 are fixed together by solder parts 95.

In this case, a solder connection is added to the second through-hole 46, and connection and fixing are performed strongly by the solder attachment land parts. Thus, even when external stress is applied to either of the substrates 40 and 50 (60), stress tends not to be applied to the solder connection part, and the solder part is resistant to the occurrence of failure such as the generation of cracking or the like.

Although embodiments of the present invention have been indicated above, the present invention is not limited by the embodiments explained by the aforementioned description and figures, and for example, embodiments such as the following are included in the technical scope of the present invention.

(1) According to the aforementioned embodiments, connection structures have been explained for connection between a main flexible circuit board 40 and a backlight flexible circuit board 50, and between a main flexible circuit board 40 and a touch panel flexible circuit board 60. However, the connection structure of the present invention may be adopted for connection between other types of flexible circuit boards. For example, if a connection is needed between a backlight flexible circuit board and a touch panel flexible circuit board, the connection structure of the present invention may be adopted for connection between such substrates.

(2) Although according to the aforementioned embodiments, a display device was indicated that was utilized by a cellular phone, the flexible circuit board connection structure of the present invention may be adopted for any display device, as exemplified by display devices used for computer monitors, display devices used for television receivers, or the like.

### DESCRIPTION OF REFERENCE CHARACTERS

1 liquid crystal display device (display device)
10 main control part
11 liquid crystal panel (display panel)
12 backlight
13 touch panel
20 backlight control part
30 touch panel control part
40 main flexible circuit board (first flexible circuit board)
41 substrate
42 connection terminal (first-side terminal)
45 first through-hole
46 second through-hole
47 solder attachment land
48 front surface (first surface)
49 rear surface (second surface)
50 backlight flexible circuit board (second flexible circuit board)
51 substrate
51a distal end part (inserted part)
51b proximal end part (non-inserted part)
52 connection terminal (second-side terminal)
53 protuberance
53 a solder attachment land
58 front surface (first surface)
59 rear surface (second surface)
60 touch panel flexible circuit board (second flexible circuit board)
61 substrate
61 a distal end part (inserted part)
61 b proximal end part (non-inserted part)
62 connection terminal (second-side terminal)
63 protuberance
63a solder attachment land
68 front surface (first surface)
69 rear surface (second surface)
90 solder part
95 solder part

1: A flexible circuit board connection structure for connection between a first flexible circuit board and a second flexible circuit board,
wherein a first through-hole and a second through-hole are formed in said first flexible circuit board,
wherein said second flexible circuit board is inserted into said first through-hole from a first surface side of said first flexible circuit board to a second surface side, and
wherein said second flexible circuit board inserted into said second surface side of said first flexible circuit board is soldered and connected to said first flexible circuit board from said first surface side of said first flexible circuit board through said second through-hole.

2: The flexible circuit board connection structure according to claim 1,
wherein said first flexible circuit board has, on at least said first surface side, a first-side terminal,
wherein said second flexible circuit board has, on at least its first surface side, a second-side terminal, and
wherein said second-side terminal is disposed opposing said second surface side of said first flexible circuit board, and said second-side terminal is soldered and connected to said first-side terminal of said first flexible circuit board through said second through-hole.

3: The flexible circuit board connection structure according to claim 2, wherein in a state where said second flexible circuit board is inserted into said first through-hole, said first-side terminal of said first flexible circuit board is superimposed on said second-side terminal of said second flexible circuit board.

4: The flexible circuit board connection structure according to claim 2,
wherein there is a plurality of said first through-hole and there is a plurality of said second-side terminals,
wherein said first through-holes are disposed on said first flexible circuit board in a zigzag pattern, and
wherein said second-side terminals are disposed on said second flexible circuit board in a zigzag pattern.

5: The flexible circuit board connection structure according to claim 1, wherein the hole width of said first through-hole is approximately the same as a substrate width of said second flexible circuit board.

6: The flexible circuit board connection structure according to claim 1,
wherein a protuberance is provided in said second flexible circuit board, and
wherein said protuberance restricts insertion of said second flexible circuit board into said first through-hole to a certain amount.

7: The flexible circuit board connection structure according to claim 1,
wherein a protuberance projecting in the width direction of said second flexible circuit board is formed in said second flexible circuit board, and
wherein the width of the substrate of said second flexible circuit board including said protuberance is larger than the hole width of said first through-hole.

8: The flexible circuit board connection structure according to claim 1,
wherein a protuberance is provided in said flexible circuit board,
wherein a solder attachment land is formed on said protuberance, and
wherein a solder attachment land is formed within said first through-hole of said first flexible circuit board and is positioned overlapping said protuberance of the second flexible circuit board inserted into said first through-hole; and said solder attachment lands are fixed by soldering.

9: The flexible circuit board connection structure according to claim 1, wherein the solder connection is performed so as to bridge at least one part of said second through-hole.

10: A display device having a touch panel, comprising:
a main control part for performing display control;
a touch panel control part for performing control of the touch panel;
a first flexible circuit board connected to said main control part; and
a second flexible circuit board connected to said touch panel control part,
wherein said first flexible circuit board and said second flexible circuit board are connected together by said connection structure according to claim 1.

11: A display device having a backlight, comprising:
a main control part for performing display control;
a backlight control part for control of the backlight;
a first flexible circuit board connected to said main control part; and
a second flexible circuit board connected to said backlight control part,
wherein said first flexible circuit board and said second flexible circuit board are connected together by said connection structure according to claim 1.

12: The display device according to claim 10, wherein said main control part performs display control of a liquid crystal panel.
